(19) United States
(12) Patent Application Publication
(10) Pub. No.: US 2026/0082801 A1
(43) Pub. Date: Mar. 19, 2026

(54) VAPOR DEPOSITION MASK, METHOD FOR MANUFACTURING VAPOR DEPOSITION MASK, AND METHOD FOR MANUFACTURING DEVICE USING VAPOR DEPOSITION MASK

(71) Applicant: CANON KABUSHIKI KAISHA, Tokyo (JP)

(72) Inventors: JUN YAMAGUCHI, Kanagawa (JP); OSAMU AKUTSU, Kanagawa (JP)

(21) Appl. No.: 19/325,838

(22) Filed: Sep. 11, 2025

(30) Foreign Application Priority Data
Sep. 18, 2024 (JP) 2024-160729

(51) Int. Cl. H10K 71/16; C23C 14/04

(52) U.S. Cl. CPC H10K 71/166; H10K 71/164; C23C 14/042

(57) ABSTRACT

A vapor deposition mask includes a base material including an opening that penetrates from a first surface of the base material to a second surface opposite to the first surface, and a recess that is provided on the first surface, and a structure that is arranged in the recess. The structure is in contact with a side surface of the recess and protrudes to a position higher than the first surface.

### BACKGROUND

### Field of the Technology

The present disclosure relates to a vapor deposition mask suitable for forming an organic EL display or the like, a method for manufacturing a vapor deposition mask, and a method for manufacturing a device using a vapor deposition mask.

### Description of the Related Art

An organic light-emitting element (organic light-emitting diode: OLED) is a device in which a plurality of light-emitting elements are arranged in a linear or matrix shape on a base material or a substrate. A light-emitting element that constitutes a light-emitting device has a pair of electrodes and a light-emitting layer that is arranged between the pair of electrodes. The luminescent color of the light-emitting element may be varied by appropriately selecting the luminescent material that constitutes the luminescent layer.

In recent years, one common process for manufacturing an organic light-emitting device using an organic light-emitting element is a vacuum film-forming process employing a vapor deposition mask. The vapor deposition mask has a plurality of openings corresponding to a pattern. During vapor deposition, the vapor deposition mask is arranged between a vapor deposition source and a substrate, thereby forming a patterned vapor deposition film reflecting the shapes of the openings on the substrate. At this time, the non-opening portions of the vapor deposition mask are positioned over areas such as drive circuits or wiring arranged outside the light-emitting area. Typically, when vapor deposition is performed with a large gap between the vapor deposition mask and the substrate, evaporated material flows around through the gap. As a result, a region referred to as vapor deposition blur or a shadow is formed at the outer periphery of the vapor-deposited film, the region being an area where the film thickness at the edge of the film decreases toward the outer end. In designing a peripheral circuit, it is necessary to secure a space for the region of this vapor deposition blur. If the spread of this region of vapor deposition blur is suppressed as much as possible, the degree of freedom in designing the peripheral circuit increases. Therefore, it is desirable that vapor deposition be performed with the minimum gap between the vapor deposition mask and the substrate.

Generally, in order to narrow the gap between the vapor deposition mask and the substrate, a magnet is used on the device side, where the substrate is arranged on the vapor deposition mask by using a magnetic material. This brings the vapor deposition mask and the substrate into intimate contact with each other during vapor deposition. At this time, if the parent material of the vapor deposition mask directly contacts the substrate, the surface of the drive circuit portion or the wiring portion on the substrate may be damaged, or foreign matter adhered to the vapor deposition mask may be transferred to the substrate side, resulting in dark spots and causing the light emission failure of the elements. In view of the above, Japanese Patent Laid-Open No. 2007-95411 proposes a technique in which a spacer made of ultraviolet-curing resin is formed on a vapor deposition mask in order to minimize the contact area between the vapor deposition mask and the substrate while maintaining a narrow gap between the vapor deposition mask and the substrate.

### SUMMARY

However, in the method proposed in Japanese Patent Laid-Open No. 2007-95411, a printing plate for screen printing is required to form the ultraviolet-curing resin that constitutes the spacer. Furthermore, once the location, in which the spacer is to be arranged, is determined, the location may not be changed unless the printing plate is replaced, and the formation of the printing plate may also require higher cost and longer time. In addition, because the positional accuracy of the screen printing itself elicits a significant impact, there is a possibility that the location, in which the spacer is arranged, varies significantly.

The present disclosure provides a vapor deposition mask with improved accuracy in the arrangement positions and sizes of structures.

According to some embodiments, a vapor deposition mask includes a base material including an opening that penetrates from a first surface of the base material to a second surface opposite to the first surface, and a recess that is provided on the first surface, and a structure that is arranged in the recess, wherein the structure is in contact with a side surface of the recess and protrudes to a position higher than the first surface.

According to some embodiments, a vapor deposition mask includes a base material including an opening that penetrates from a first surface of the base material to a second surface opposite to the first surface, a film that is arranged on the first surface and has a hole for partially exposing the first surface, wherein the base material and the film form a recess, a surface of the film that forms the hole being a side surface of the recess, and a region of the first surface that is exposed by the hole being a bottom surface of the recess, and a structure, which is in contact with the side surface of the recess and protrudes to a position higher than the film, is arranged in the recess.

According to some embodiments, a method for manufacturing a vapor deposition mask, the method includes forming a recess in a base material, and manufacturing a structure in the recess by using an injection method.

Features of the present disclosure will become apparent from the following description of embodiments with reference to the attached drawings. The following description of embodiments is described by way of example.

### BRIEF DESCRIPTION OF THE DRAWINGS

FIG. 1 is a plan view illustrating an example of a vapor deposition mask according to a first embodiment.

FIG. 2 is an enlarged view of a part of the vapor deposition mask according to the first embodiment.

FIG. 3 is a schematic cross-sectional view of the vapor deposition mask according to the first embodiment.

FIGS. 4A to 4D are views illustrating an example of a method for manufacturing the vapor deposition mask according to the first embodiment.

FIG. 5 is a schematic cross-sectional view of a substrate and the vapor deposition mask according to the first embodiment.

FIGS. 6A and 6B are views illustrating another example of the vapor deposition mask according to the first embodiment.

FIG. 7 is a plan view illustrating a vapor deposition mask according to a second embodiment.

FIG. 8 is an enlarged view of a part of the vapor deposition mask according to the second embodiment.

FIGS. 9A and 9B are schematic cross-sectional views of the vapor deposition mask according to the second embodiment.

FIGS. 10A to 10E are views illustrating an example of a method for manufacturing the vapor deposition mask according to the second embodiment.

FIGS. 11A to 11D are views illustrating an example of a method for manufacturing a device according to a third embodiment.

### DESCRIPTION OF THE EMBODIMENTS

Hereinafter, embodiments of the present disclosure will be appropriately described in detail with reference to the drawings. However, the present disclosure is not limited to the following embodiments. Furthermore, regarding aspects that are not specifically indicated in the following description or not specifically illustrated in the drawings, known or publicly known techniques in the relevant technical field may be applied.

### First Embodiment

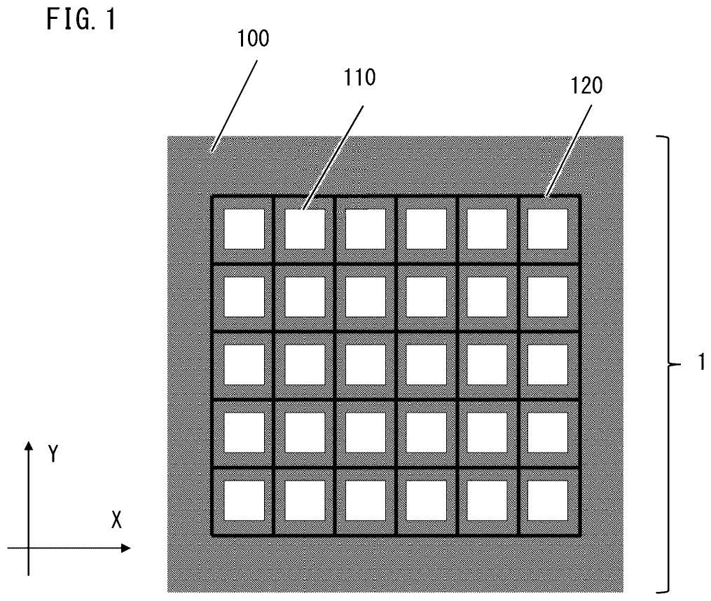

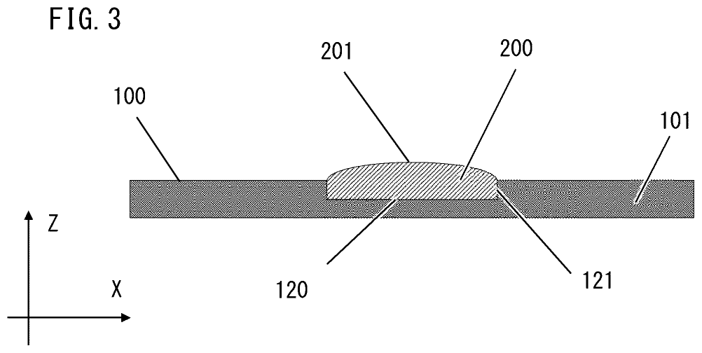

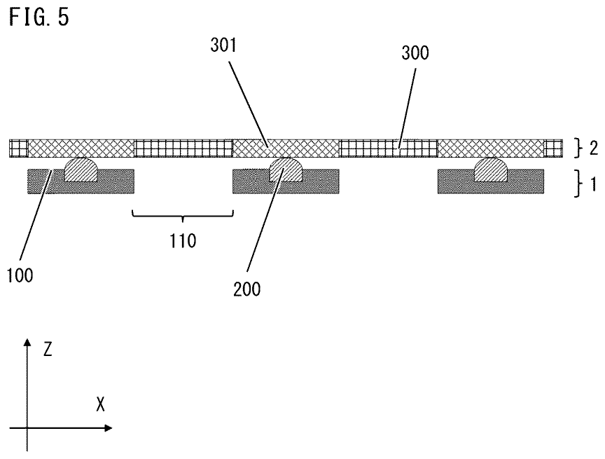

FIG. 1 is a plan view of a vapor deposition mask according to this embodiment. FIG. 1 illustrates a plan view of the vapor deposition mask 1 on the surface side thereof that contacts (faces) a substrate 2 (see FIG. 5) during vapor deposition. Here, the surface side that contacts the substrate 2 is defined as a first surface 100. The vapor deposition mask 1 has a base material 101 (see FIG. 3) including openings 110 that penetrate from the first surface 100 to a second surface opposite to the first surface 100, and a recess 120 that is provided on the first surface 100. The recess 120 is formed in a recessed shape with respect to the first surface 100. When the surface side that contacts the substrate 2 is defined as the upper side, the recess 120 is formed at a position lower than the first surface 100.

The vapor deposition mask 1 is made of the plate-shaped base material 101 mainly composed of a metal or alloy of a magnetic material but may be composed as a combination of a non-magnetic metal and resin. The plate thickness of the vapor deposition mask 1 is not particularly limited but is preferably in the range of approximately 50 μm to 1 mm. The openings 110 are provided to form a vapor deposition film required for enabling organic light-emitting elements or the like to operate. Although not illustrated in FIG. 1, the vapor deposition mask 1 may be provided with an opening for an alignment mark used to align with the substrate 2 during vapor deposition, or with an opening for a jig such as a screw or a pin required to fix the vapor deposition mask 1 to a frame. Furthermore, openings or notches may also be provided for purposes other than forming organic light-emitting elements, such as for structural convenience of the device.

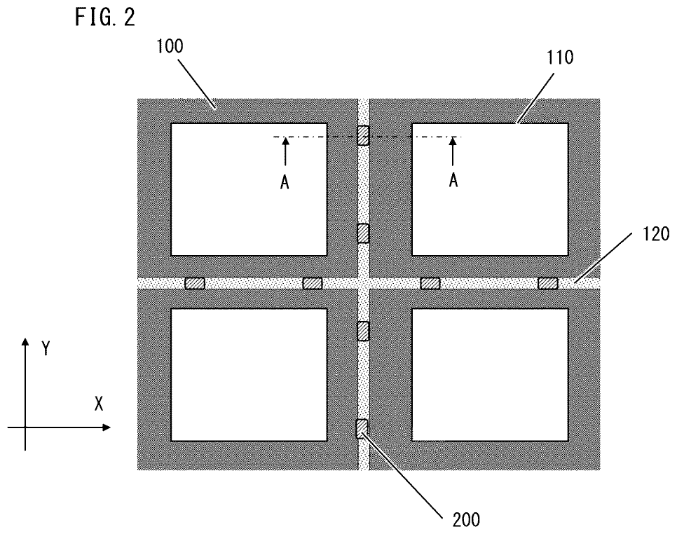

FIG. 2 is an enlarged view of the surface side of the vapor deposition mask 1 that contacts the substrate 2, that is, a part of the first surface 100. The recess 120 is made of the same material as the vapor deposition mask 1 and is formed by processing the first surface 100. Structures 200 are made of a material different from that of the base material 101 of the vapor deposition mask 1 and are arranged in at least a part of a region in the recess 120. The structures 200 are not necessarily required to be arranged so as to fill the recess 120 and may be arranged so as to contact a part of a region of both side surfaces of the recess 120 (e.g., fill a part of the region in the recess 120). That is, the vapor deposition mask 1 may have a plurality of structures 200, and the structures 200 may be provided in the recess 120 with specified intervals therebetween. In particular, in order to reduce the amount of the material used to form the structures 200, it is desirable to arrange the structures 200 in a scattered manner as illustrated in FIG. 2.

Here, the horizontal direction in FIG. 2 is defined as the X-direction (first direction), and the vertical direction orthogonal to the X-direction in FIG. 2 is defined as the Y-direction (second direction). Furthermore, a portion of the recess 120 that extends in the X-direction is defined as a first portion, and a portion thereof that extends in the Y-direction is defined as a second portion. Note that the direction orthogonal to both the X-direction and the Y-direction is defined as the Z-direction. FIGS. 1 and 2 are views of the vapor deposition mask 1 when viewed in the Z-direction. Furthermore, the structures 200 may be arranged as first structures in the first portion and arranged as second structures in the second portion. In this case, it is preferable that the smaller of the dimension of the first structures in the X-direction and the dimension of the second structures in the Y-direction be at least 50 μm. Furthermore, it is preferable that the greater of the dimension of the first structures in the X-direction and the dimension of the second structures in the Y-direction be not more than 200 μm.

FIG. 3 is a schematic cross-sectional view taken along line A-A in FIG. 2. A structure 200 is formed in the recess 120, with at least a part thereof being in contact with a side surface 121 of the recess 120. The structure 200 may overflow onto the first surface 100 of the vapor deposition mask 1. However, by adjusting the amount of the structure 200, it is possible to form the structure 200 such that it hardly overflows from the recess 120. By forming the structure 200 so as not to overflow, its formed position is defined by the recess 120. Therefore, compared to a case in which the structure 200 is formed on a flat surface without the recess 120, it is possible to further improve the positional accuracy of the structure 200. Furthermore, a top portion 201 of the structure 200 is formed so as to be accommodated in the recess 120 when viewed in plan (Z-direction) as illustrated in FIG. 1 or 2 and is formed to protrude to a position higher than the first surface 100 of the vapor deposition mask 1.

The depth of the recess 120 is not particularly limited, as long as it is shorter than the thickness of the vapor deposition mask 1 (i.e., the recess 120 does not penetrate the vapor deposition mask 1). However, it is preferably in the range of approximately 1 μm to 50 μm. FIG. 1 (a plan view of the first surface 100) illustrates the recess 120 formed in a lattice shape that surrounds each of the plurality of openings 110. However, the pattern of the recess 120 is not particularly limited, as long as the structures 200 are appropriately arranged in the recess 120 such that the substrate 2 and the vapor deposition mask 1 do not contact each other at portions other than the structures 200. For example, the recess 120 may be configured in a groove shape that extends in a direction parallel to the first surface 100, or may be arranged so as to surround the openings 110. When a plurality of openings 110 are provided in the base material 101, the recess 120 may include a portion that extends between the openings 110. Alternatively, a plurality of recesses 120 may be provided in an isolated and discontinuous pattern. In addition, the recess 120 may have a ring shape that surrounds the structures 200.

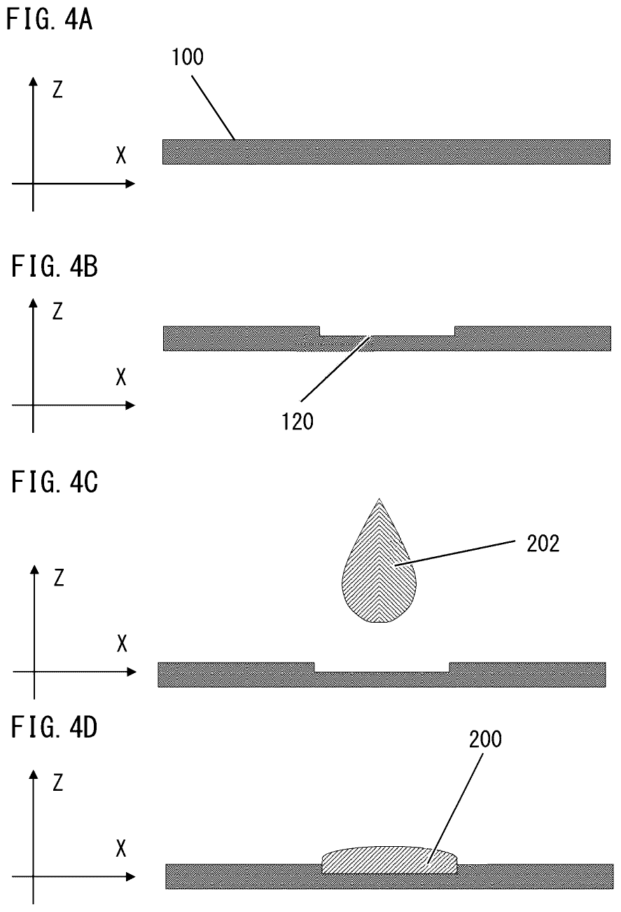

FIGS. 4A to 4D (cross-sectional schematic views) illustrate an example of a method for manufacturing the vapor deposition mask 1. In order to form the recess 120 on the first surface 100 of the base material 101 of the vapor deposition mask 1 (the openings not illustrated) illustrated in FIG. 4A, etching is performed or laser light is applied after a photolithography process. As a result, the recess 120 is formed in the base material 101 as illustrated in FIG. 4B. The manufacturing method is not particularly limited, as long as the recess 120 is formed with a certain degree of positional accuracy.

Next, as illustrated in FIG. 4C, a liquid material 202, such as resin or metal ink, is dropped into the recess 120. As a result, the structure 200 as illustrated in FIG. 4D is manufactured. For forming the structure 200, it is desirable to use an injection method such as an inkjet method or a method using a dispenser. However, the method is not particularly limited, as long as the structure 200 is formed at any position in the recess 120.

FIG. 5 is an enlarged cross-sectional view illustrating an example of the relationship between the vapor deposition mask 1 and the substrate 2 in a vacuum device when a vapor deposition film is deposited on the substrate 2 using the vapor deposition mask 1 according to this embodiment. The substrate 2 is a substrate on which organic light-emitting elements or the like are formed, and is mainly a glass substrate or a silicon wafer. Elements such as transistors for driving the organic light-emitting elements are formed on the substrate 2 in advance. The surface of the substrate 2 that faces the vapor deposition mask 1 is divided into a vapor deposition region 300 in which a vapor deposition film is formed and a non-vapor deposition region 301 in which no vapor deposition film is formed. The non-vapor deposition region 301 includes circuits and wiring for driving the organic light-emitting elements, as well as scribe lines for cutting between the chips of the organic light-emitting elements that are formed on the substrate 2. On the vapor deposition region 300 of the substrate 2, material evaporated from a vapor deposition source passes through the openings 110 of the vapor deposition mask 1 and is deposited on the surface of the substrate 2. As a result, a pattern reflecting the shape of the openings 110 of the vapor deposition mask 1 is formed on the vapor deposition region 300 of the substrate 2.

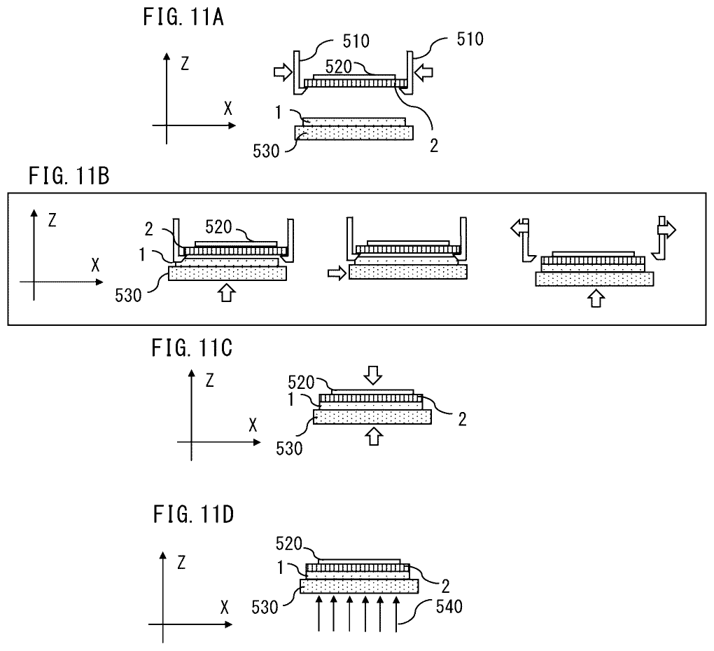

During vapor deposition, the vapor deposition mask 1 is attracted to the side of the substrate 2 by a magnet 520 (see FIGS. 11A to 11D) installed on the device, and the non-vapor deposition region 301 of the substrate 2 comes into contact with the structures 200. In addition, the structures 200 are limited in size and reduced in a direction parallel to the first surface 100 of the vapor deposition mask 1 by the recess 120. As a result, the contact area between the substrate 2 and the vapor deposition mask 1 via the structures 200 is reduced. This makes it possible to reduce the light emission failure of the light-emitting elements that is caused by damage to the substrate 2 or by foreign matter transferred onto the substrate 2. Note that it is more desirable for the structures 200 to contact regions such as scribe lines without elements or wiring, rather than regions such as drive circuits with elements or wiring.

When the structures 200 are arranged so as to contact the scribe lines, the width of the scribe lines may be constrained by the size of the structures 200. In such a case, if the structures 200 are finely manufactured, it is possible to reduce the width of the scribe lines. If the width of the scribe lines is reduced on one substrate, it is possible to increase the yield of chips manufactured from this one substrate, thereby achieving the cost reduction of the chips.

At this time, the gap between the first surface 100 and the substrate 2 is preferably in the range of approximately 5 μm to 50 μm. That is, it is preferable to adjust the structures 200 (tops 201) so that they protrude from the first surface 100 by at least 5 μm and not more than 50 μm. If the gap becomes too small, the risk of the non-opening regions of the vapor deposition mask 1 contacting the substrate 2 increases. On the other hand, if the gap becomes too large, the spread of vapor deposition blur increases. If the vapor deposition blur is large, the space for the vapor deposition blur secured in the non-vapor deposition region 301 increases. On the other hand, by finely manufacturing the structures 200 as in this embodiment, it is possible to arrange the structures on the substrate side, avoiding elements, wiring, circuits, and the like, while maintaining an appropriate gap between the first surface 100 and the substrate 2. This makes it possible to reduce the chip size.

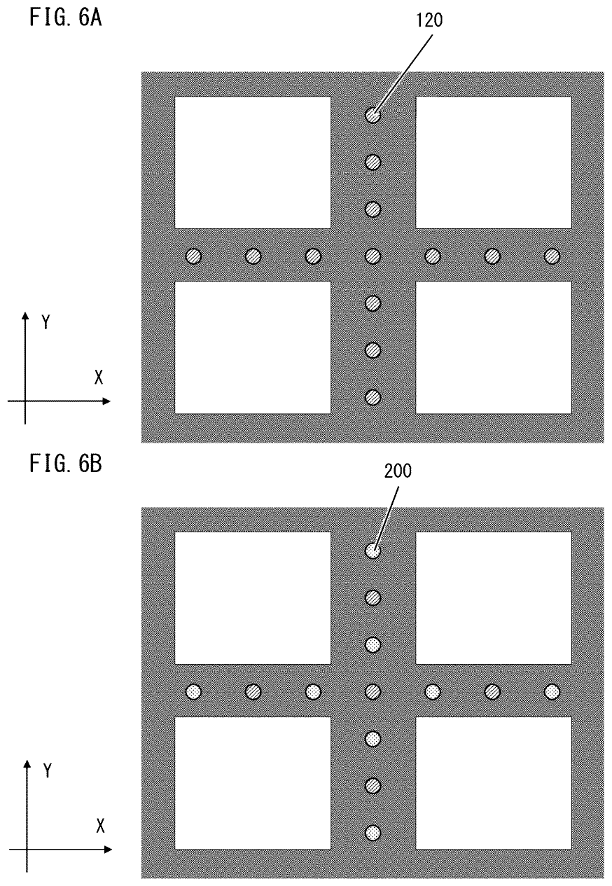

The recess 120 may be formed not in a groove shape, but as a plurality of scattered holes as illustrated in FIG. 6A, or in a form that combines holes and grooves. When the recess 120 is formed as a plurality of scattered holes, it is not necessarily required to form the structures 200 in all the holes. The structures 200 may be formed only in some of the scattered holes as illustrated in FIG. 6B. Furthermore, a plurality of recesses 120 may be arranged in a scattered manner so as to surround the openings 110.

In the embodiment described above, the structures 200 are formed at any position in the recess 120 that is formed in the vapor deposition mask 1 in advance. This makes it possible to obtain a vapor deposition mask with improved accuracy in the arrangement positions and sizes of the spacers. By providing in advance the recess 120 at a position overlapping a region without elements or wiring, such as the scribe lines on the side of the substrate, it is possible to reduce the width of the scribe lines if it is determined by the size of the structures 200. This makes it possible to increase the yield of chips manufactured from one substrate. Furthermore, it is also possible to arrange the structures on the substrate side, avoiding elements, wiring, circuits, and the like, while maintaining an appropriate gap between the first surface 100 and the substrate 2. This makes it possible to reduce the chip size.

During vapor deposition, the size of the structures 200 is small in the direction parallel to the first surface 100. Therefore, it is possible to arrange the vapor deposition mask such that the structures 200 are positioned at a location avoiding elements, wiring, circuits, and the like of the substrate 2, while maintaining a narrow gap between the substrate 2 and the vapor deposition mask 1. This makes it possible to reduce vapor deposition blur and attain the reduction of the chip size while ensuring its reliability. Furthermore, the manufacturing method of this embodiment enables formation without a printing plate. Therefore, compared to a case in which the structures are formed by screen printing, it is possible to further reduce the chip manufacturing cost. Note that the matters described with reference to FIGS. 5, 6A, and 6B may also be applied to the second embodiment described below.

### Second Embodiment

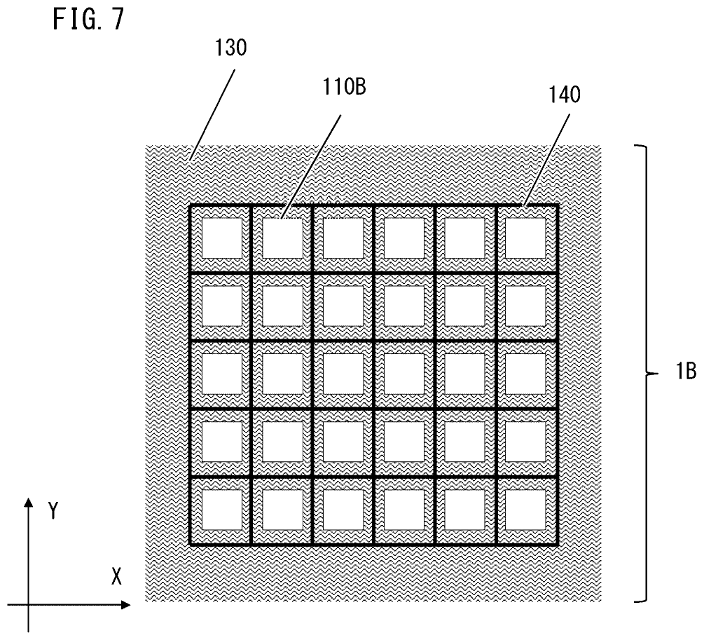

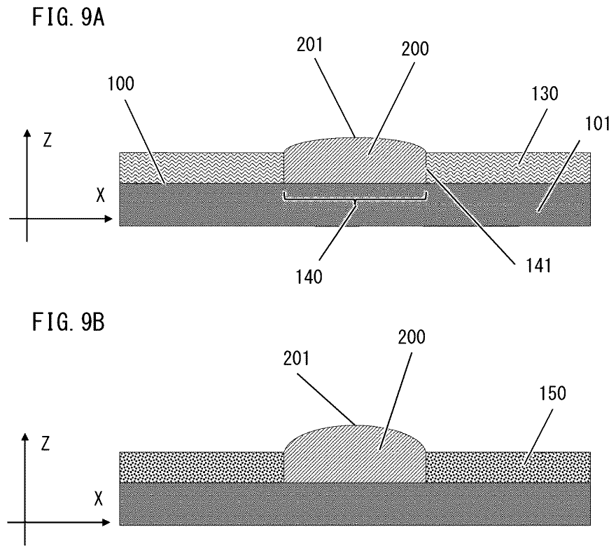

FIG. 7 is a plan view of a vapor deposition mask according to this embodiment. FIG. 7 shows a plan view of the vapor deposition mask 1B on the surface side thereof that contacts a substrate 2 during vapor deposition. Here, the surface side that contacts the substrate 2 is defined as a first surface 100 (see FIGS. 9A and 9B). The vapor deposition mask 1B has a base material 101 including openings 110B that penetrate from the first surface 100 to a second surface opposite to the first surface 100, and a film 130 that is arranged on the first surface 100 and has a hole for partially exposing the first surface 100. The film 130 is processed to form a hole that penetrates the film 130 so as to expose the first surface 100. As a result, a recess 140 is formed, in which a region of the film 130 that forms the hole is defined as a side surface 141 (see FIGS. 9A and 9B), and in which a region of the first surface 100 that is exposed by the hole is defined as a bottom surface. When the surface side that contacts the substrate 2 is defined as the upper side, the recess 140 is formed at a position lower than the surface of the film 130.

The vapor deposition mask 1B is made of the plate-shaped base material 101 mainly composed of a metal or alloy of a magnetic material, but may be composed as a combination of a non-magnetic metal or resin. The plate thickness of the vapor deposition mask 1B is not particularly limited but is preferably in the range of approximately 50 μm to 1 mm. The openings 110B are provided to form a vapor deposition film required for enabling organic light-emitting elements to operate. Although not illustrated in FIG. 7, the vapor deposition mask 1B may be provided with an opening for an alignment mark used to align with the substrate 2 during vapor deposition, or with an opening for a jig such as a screw or a pin required to fix the vapor deposition mask 1B to a frame. Furthermore, openings or notches may also be provided for purposes other than forming organic light-emitting elements, such as for structural convenience of the device.

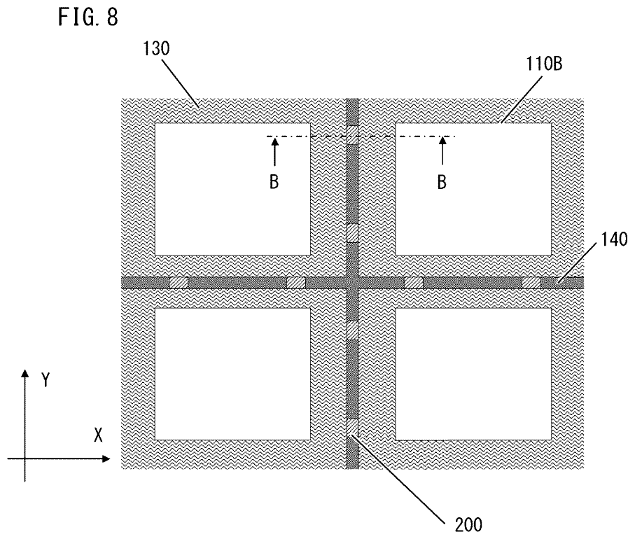

FIG. 8 is an enlarged view of the surface side of the vapor deposition mask 1B that contacts the substrate 2, that is, a part of the first surface 100. The film 130 is formed to create the recess 140 in the vapor deposition mask 1B. The material constituting the bottom surface of the recess 140 (i.e., the base material 101 of the vapor deposition mask 1B) and the material constituting the film 130 are different materials. Structures 200 are made of a material different from that of the base material 101 of the vapor deposition mask 1B and are arranged on at least a part of a region in the recess 140. The structures 200 are not necessarily required to be arranged so as to fill the recess 140 and may be arranged so as to be in contact with a part of a region of both side surfaces of the recess 140 (e.g., fill a part of the region in the recess 140). That is, the vapor deposition mask 1B may have a plurality of structures 200, and the structures 200 may be provided in the recess 140 with specified intervals therebetween. In particular, in order to reduce the amount of material used to form the structures 200, it is desirable to arrange the structures 200 in a scattered manner.

Here, in FIG. 8, a portion of the recess 140 that extends in the X-direction (first direction) is defined as a first portion, and a portion thereof that extends in the Y-direction (second direction) is defined as a second portion. Furthermore, the structures 200 may be arranged as first structures in the first portion and arranged as second structures in the second portion. In this case, it is preferable that the smaller of the dimension of the first structures in the X-direction and the dimension of the second structures in the Y-direction be at least 50 μm. On the other hand, it is preferable that the greater of the dimension of the first structures in the X-direction (first direction) and the dimension of the second structures in the Y-direction (second direction) be not more than 200 μm.

FIG. 9A is a schematic cross-sectional view taken along line B-B in FIG. 8. A structure 200 is formed in the recess 140, with at least a part thereof being in contact with the side surface 141 of the recess 140. The structure 200 may overflow onto the film 130. However, by adjusting the amount of the structure 200, it is possible to form the structure 200 such that it hardly overflows from the recess 140. By forming the structure 200 so as not to overflow, its formed position is defined by the recess 140. Therefore, compared to a case in which the structure 200 is formed on a flat surface without the recess 140, it is possible to further improve the positional accuracy of the structure 200. A top portion 201 of the structure 200 is formed in the recess 140 and is formed to protrude to a position higher than the film 130 of the vapor deposition mask 1B.

The depth of the recess 140 is not particularly limited. However, it is preferably in the range of approximately 1 μm to 5 μm. FIG. 7 (a plan view of the film) illustrates the recess 140 formed in a lattice shape that surrounds each of the plurality of openings 110B. However, the pattern of the recess 140 is not particularly limited, as long as the structures 200 are appropriately arranged in the recess 140 such that the substrate 2 and the vapor deposition mask 1B do not contact each other. For example, the recess 140 may be configured in a groove shape that extends in a direction parallel to the film 130, or may be arranged so as to surround the openings 110B. When a plurality of openings 110B are provided in the base material 101, the recess 140 may include a portion that extends between the openings 110B. Alternatively, a plurality of recesses 140 may be provided in an isolated and discontinuous pattern. In addition, the recess 140 may have a ring shape that surrounds the structures 200.

FIG. 9B illustrates an example in which the film 130 in FIG. 9A is replaced with a liquid-repellent film 150 to enhance the liquid repellency with respect to the structures 200. When forming the structures 200, the tops 201 of the structures 200 are made higher depending on the liquid repellency of the film constituting the liquid-repellent film 150. If the tops 201 of the structures 200 are made higher, the gap between the substrate 2 and the vapor deposition mask 1B during vapor deposition is widened, making it easier to avoid the unnecessary contact between the non-opening regions of the vapor deposition mask 1B and the substrate 2. During vapor deposition, the non-opening regions of the vapor deposition mask 1B are typically attracted to the substrate side by a magnet 520. Therefore, the non-opening regions between the structures 200 are deflected in the substrate direction. Therefore, it is necessary to determine the arrangement of the structures 200 such that the non-opening regions and the substrate 2 do not make unnecessary contact each other. If the gap between the vapor deposition mask 1B and the substrate 2 is widened as illustrated in FIG. 9B, there are advantages in that the number of the structures 200 to be arranged is reduced, and the load on the arrangement of the structures 200 is decreased.

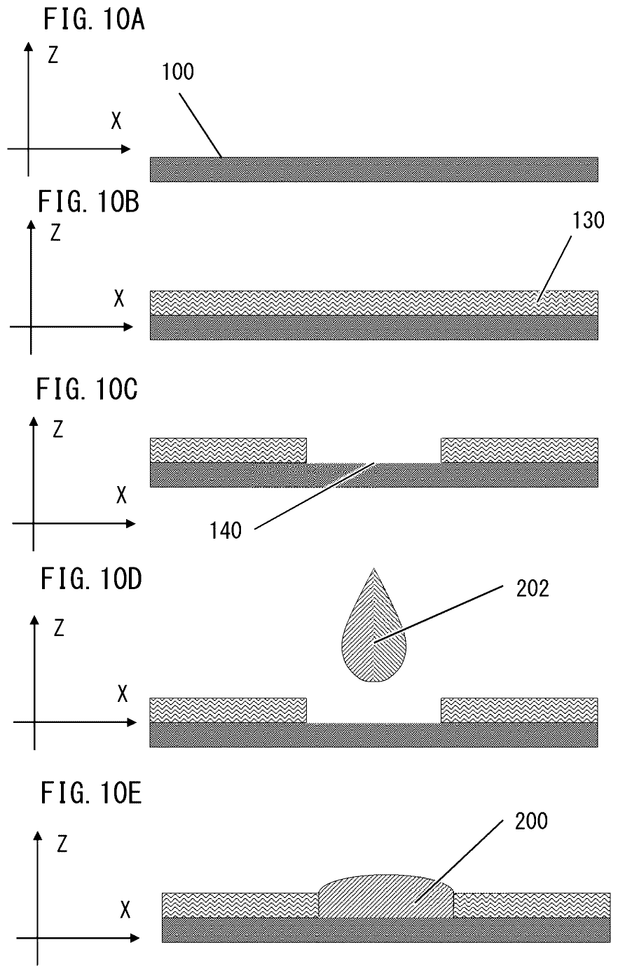

FIGS. 10A to 10E (cross-sectional schematic views) illustrate an example of a method for manufacturing the vapor deposition mask 1B. In order to form the film 130 on the first surface 100 of the base material 101 of the vapor deposition mask 1B (the openings not illustrated) illustrated in FIG. 10A, a sputtering method or the like may be used. As a result, the film 130 (150) is formed on the base material 101 as illustrated in FIG. 10B. The film-forming method is not particularly limited, as long as the film 130 is formed with a certain degree of thickness accuracy. Furthermore, the material of the film 130 is not particularly limited and may be selected from an oxide, a nitride, a carbide, or the like.

As illustrated in FIG. 10C, in order to form the recess 140 in the film 130, etching is performed or laser light is applied after a photolithography process. As a result, the recess 140 is formed as illustrated in FIG. 10C. The manufacturing method is not particularly limited, as long as the recess 140 is formed with a certain degree of positional accuracy. Next, as illustrated in FIG. 10D, a liquid material 202, such as resin or metal ink, is dropped into the recess 140. As a result, the structure 200 as illustrated in FIG. 10E is manufactured. For forming the structure 200, it is desirable to use an injection method such as an inkjet method or a method using a dispenser. However, the method is not particularly limited, as long as the structure 200 is formed at any position in the recess 140.

According to this embodiment, similar to the first embodiment, the contact between the vapor deposition mask 1B and the substrate 2 is limited to the contact between the structures 200 and the substrate 2, thereby making it possible to suppress damage to the film on the substrate or the adhesion of foreign matter thereto when forming the organic light-emitting elements by vapor deposition. As a result, reducing the risk of the failure of the light-emitting elements enables an improvement in the quality of the organic light-emitting elements.

### Third Embodiment

Next, a part of a method for manufacturing a device such as a light-emitting device will be described with reference to FIGS. 11A to 11D. However, the present disclosure is not limited thereto.

In a vapor deposition chamber, for example, by the following configuration, at least one of an electrode of an organic light-emitting element and a plurality of layers included in an organic layer may be formed on a substrate to be vapor-deposited. A part of a method for manufacturing an organic light-emitting element includes: a step of bringing a vapor deposition mask having a plurality of openings 110 (110B) to face a substrate to be vapor-deposited on which a first electrode and an organic layer are arranged; and a step of aligning the substrate to be vapor-deposited with the vapor deposition mask 1 (1B). In addition, the method includes: a step of bringing the substrate to be vapor-deposited into contact with the vapor deposition mask 1 (1B); and a step of forming a second electrode by vapor-depositing a vapor deposition material 540 onto the substrate through the openings 110 (110B) of the vapor deposition mask 1 (1B).

First, as illustrated in FIG. 11A, a substrate 2 (substrate to be vapor-deposited) held by a substrate holding arm 510 is brought to face the vapor deposition mask 1 (1B), which is arranged on a mask stage 530 and has the plurality of openings 110 (110B). Here, any of a first electrode, an insulating layer for electrically isolating the first electrode, and an organic layer may be formed on the substrate 2. Furthermore, wiring, pads, circuits for driving organic light-emitting elements, and the like may also be formed thereon. The vapor deposition mask 1 (1B) according to one of the first and second embodiments may be used as the vapor deposition mask.

Next, as illustrated in FIG. 11B, for example, one or both of the substrate 2 and the vapor deposition mask 1 are moved to align the substrate 2 with the vapor deposition mask 1. Then, as illustrated in FIG. 11C, the substrate 2 and the vapor deposition mask 1 are brought into contact with each other by magnetic force. At this time, the substrate 2 and the vapor deposition mask 1 are brought into contact with each other by the magnetic force between a magnet 520, which is arranged on the surface of the substrate 2 opposite to the vapor deposition mask 1, and the vapor deposition mask 1 having metal. Next, as illustrated in FIG. 11D, a vapor deposition material 540 is vapor-deposited onto the substrate 2 through the openings of the vapor deposition mask 1, thereby forming a vapor deposition pattern on the substrate 2.

The method for manufacturing the organic light-emitting element here is merely an example, and the present disclosure is not limited thereto. The light-emitting element has a plurality of functional layers, and a vapor deposition apparatus for manufacturing the light-emitting element is configured to include a plurality of vapor deposition chambers corresponding to the plurality of functional layers. Furthermore, in addition to the vapor deposition chamber, the vapor deposition apparatus may also include a plurality of process chambers, such as a charge chamber, a pretreatment chamber, a transfer chamber, a relay chamber, and a substrate stock chamber.

The embodiments described above may be appropriately modified without departing from the spirit of the technical concept. Note that the disclosed content of the present specification includes not only the matters described herein, but also all matters understandable from the present specification and the accompanying drawings attached thereto.

The present disclosure encompasses the following configurations and methods.

(Configuration 1) A vapor deposition mask comprising:
a base material including an opening that penetrates from a first surface of the base material to a second surface opposite to the first surface, and a recess that is provided on the first surface; and
a structure that is arranged in the recess, wherein
the structure is in contact with a side surface of the recess and protrudes to a position higher than the first surface.

(Configuration 2) A vapor deposition mask comprising:
a base material including an opening that penetrates from a first surface of the base material to a second surface opposite to the first surface;
a film that is arranged on the first surface and has a hole for partially exposing the first surface, wherein
the base material and the film form a recess, a surface of the film that forms the hole being a side surface of the recess, and a region of the first surface that is exposed by the hole being a bottom surface of the recess,
a structure, which is in contact with the side surface of the recess and protrudes to a position higher than the film, is arranged in the recess.

(Configuration 3) The vapor deposition mask according to Configuration 1 or 2, wherein
the recess is configured in a groove shape that extends, on the first surface, in a direction parallel to the first surface.

(Configuration 4) The vapor deposition mask according to Configuration 1 or 2, wherein
the recess is arranged so as to surround the opening in a plan view of the first surface.

(Configuration 5) The vapor deposition mask according to Configuration 1 or 2, wherein
the base material is provided with a plurality of openings, and
the recess includes a portion that extends between the plurality of openings in a plan view of the first surface.

(Configuration 6) The vapor deposition mask according to Configuration 1 or 2, wherein
the base material is provided with a plurality of openings, and
the recess includes a portion having a lattice shape that surrounds each of the plurality of openings in a plan view of the first surface.

(Configuration 7) The vapor deposition mask according to Configuration 1 or 2, comprising:
a plurality of the structures, wherein
the plurality of the structures are provided in the recess with specified intervals therebetween.

(Configuration 8) The vapor deposition mask according to Configuration 1 or 2, comprising:
a plurality of the structures, wherein
the plurality of the structures includes a first structure and a second structure,
the recess includes a first portion that extends in a first direction in a plan view of the first surface and a second portion that extends in a second direction orthogonal to the first direction,
the first structure is provided in the first portion, and
the second structure is provided in the second portion.

(Configuration 9) The vapor deposition mask according to Configuration 8, wherein
the smaller of the dimension of the first structure in the first direction and the dimension of the second structure in the second direction is at least 50 μm.

(Configuration 10) The vapor deposition mask according to Configuration 8, wherein
the smaller of the dimension of the first structure in the first direction and the dimension of the second structure in the second direction is at least 200 μm.

(Configuration 11) The vapor deposition mask according to Configuration 1 or 2, comprising:
a plurality of the recesses, wherein
the plurality of the recesses are arranged in a scattered manner.

(Configuration 12) The vapor deposition mask according to Configuration 11, wherein
the plurality of the recesses are arranged so as to surround the opening.

(Configuration 13) The vapor deposition mask according to any one of Configurations 1 to 12, wherein
the structure protrudes from the first surface by at least 5 μm and not more than 50 μm.

(Configuration 14) The vapor deposition mask according to any one of Configurations 1 to 13, wherein
the structure has a material different from that of the base material.

(Configuration 15) The vapor deposition mask according to any one of Configurations 1 to 14, wherein
the structure is formed by an injection method.

(Configuration 16) The vapor deposition mask according to any one of Configurations 1 to 15, wherein
the base material is mainly composed of a magnetic material.

(Configuration 17) The vapor deposition mask according to Configuration 2, wherein
the film is composed of a material having high liquid repellency with respect to the structure.

(Configuration 18) The vapor deposition mask according to any one of Configurations 1 to 17, wherein
the opening and the recess do not overlap in a plan view of the first surface.

(Configuration 19) The vapor deposition mask according to any one of Configurations 1 to 18, wherein
the structure contains a resin.

(Method 1) A method for manufacturing a vapor deposition mask, the method comprising:
a step of forming a recess in a base material; and
a step of manufacturing a structure in the recess by using an injection method.

(Method 2) The method for manufacturing the vapor deposition mask according to Method 1, wherein
the step of forming the recess is a step of forming the recess by performing etching of the base material.

(Method 3) The method for manufacturing the vapor deposition mask according to Method 1, wherein
the step of forming the recess is a step of forming the recess by applying laser light to the base material.

(Method 4) A method for manufacturing the vapor deposition mask, the method comprising:
a step of forming a film on a base material;
a step of forming a recess in the film; and
a step of manufacturing a structure in the recess by using an injection method.

(Method 5) The method for manufacturing the vapor deposition mask according to Method 4, wherein
the step of forming the recess is a step of forming the recess by performing etching of the film by a photolithography process.

(Method 6) The method for manufacturing the vapor deposition mask according to Method 4, wherein
the step of forming the recess is a step of forming the recess by applying laser light to the film.

(Method 7) A method for manufacturing a device, the method comprising:
a step of aligning the vapor deposition mask according to any one of Configurations 1 to 19 with a substrate to be vapor-deposited; and
a step of forming a vapor deposition film by depositing a vapor deposition material onto the substrate to be vapor-deposited by using the vapor deposition mask.

(Method 8) The method for manufacturing the device according to Method 7, wherein
the vapor deposition film is an organic layer of an organic light-emitting element.

According to the present embodiments, it is possible to provide a vapor deposition mask with improved accuracy in the arrangement positions and sizes of structures.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-160729, filed on Sep. 18, 2024 which is hereby incorporated by reference herein in its entirety.

What is claimed is:

1. A vapor deposition mask comprising:
a base material including an opening that penetrates from a first surface of the base material to a second surface opposite to the first surface, and a recess that is provided on the first surface; and
a structure that is arranged in the recess, wherein
the structure is in contact with a side surface of the recess and protrudes to a position higher than the first surface.

2. A vapor deposition mask comprising:
a base material including an opening that penetrates from a first surface of the base material to a second surface opposite to the first surface;
a film that is arranged on the first surface and has a hole for partially exposing the first surface, wherein
the base material and the film form a recess, a surface of the film that forms the hole being a side surface of the recess, and a region of the first surface that is exposed by the hole being a bottom surface of the recess, and
a structure, which is in contact with the side surface of the recess and protrudes to a position higher than the film, is arranged in the recess.

3. The vapor deposition mask according to claim 1, wherein
the recess is configured in a groove shape that extends, on the first surface, in a direction parallel to the first surface.

4. The vapor deposition mask according to claim 2, wherein
the recess is configured in a groove shape that extends, on the first surface, in a direction parallel to the first surface.

5. The vapor deposition mask according to claim 1, wherein
the recess is arranged so as to surround the opening in a plan view of the first surface.

6. The vapor deposition mask according to claim 1, wherein
the base material is provided with a plurality of openings, and
the recess includes a portion that extends between the plurality of openings in a plan view of the first surface.

7. The vapor deposition mask according to claim 1, wherein
the base material is provided with a plurality of openings, and
the recess includes a portion having a lattice shape that surrounds each of the plurality of openings in a plan view of the first surface.

8. The vapor deposition mask according to claim 1, comprising:
a plurality of the structures, wherein
the plurality of the structures are provided in the recess with specified intervals therebetween.

9. The vapor deposition mask according to claim 1, wherein
the structure protrudes from the first surface by at least 5 μm and not more than 50 μm.

10. The vapor deposition mask according to claim 1, wherein
the structure has a material different from that of the base material.

11. The vapor deposition mask according to claim 1, wherein
the structure is formed by an injection method.

12. The vapor deposition mask according to claim 1, wherein
the base material is mainly composed of a magnetic material.

13. The vapor deposition mask according to claim 2, wherein
the film is composed of a material having high liquid repellency with respect to the structure.

14. The vapor deposition mask according to claim 1, wherein
the opening and the recess do not overlap in a plan view of the first surface.

15. The vapor deposition mask according to claim 1, wherein
the structure contains a resin.

16. The vapor deposition mask according to claim 2, wherein
the opening and the recess do not overlap in a plan view of the first surface.

17. The vapor deposition mask according to claim 2, wherein
the structure contains a resin.

18. A method for manufacturing a vapor deposition mask, the method comprising:
forming a recess in a base material; and
manufacturing a structure in the recess by using an injection method.

19. A method for manufacturing a device, the method comprising:
aligning the vapor deposition mask according to claim 1 with a substrate to be vapor-deposited; and
forming a vapor deposition film by depositing a vapor deposition material onto the substrate to be vapor-deposited by using the vapor deposition mask.

20. The method for manufacturing the device according to claim 19, wherein
the vapor deposition film is an organic layer of an organic light-emitting element.
